(19) United States
(12) Patent Application Publication
(10) Pub. No.: US 2023/0115802 A1
(43) Pub. Date: Apr. 13, 2023

(54) DISPLAY DEVICE AND METHOD OF MANUFACTURING THE SAME

(71) Applicant: Samsung Display Co., Ltd., Yongin-si (KR)

(72) Inventors: SANG-CHUL BYUN, Anyang-si (KR); HAYOUNG CHOI, Hwaseong-si (KR)

(21) Appl. No.: 17/878,315

(22) Filed: Aug. 1, 2022

(30) Foreign Application Priority Data
Oct. 8, 2021 (KR) 10-2021-0133837

(51) Int. Cl. H01L 27/32; H01L 51/56

(52) U.S. Cl. CPC H01L 27/3276; H01L 51/56; H01L 2227/323

(57) ABSTRACT

A display device includes a substrate including a display area and a pad area positioned at one side of the display area, a first pad electrode disposed on the pad area of the substrate, a second pad electrode disposed on the pad area of the substrate to be spaced apart from the first pad electrode, a dam structure disposed between the first pad electrode and the second pad electrode, an adhesive member disposed on the first pad electrode, the second pad electrode and the dam structure, where the adhesive member includes a first conductive ball, a second conductive ball and a, and an electronic component disposed on the adhesive member. The dam structure includes a photo-curable polymer material and is formed by an inkjet process. The adhesive member includes a thermosetting polymer material, and is formed by an inkjet process.

This application claims priority to Korean Patent Application No. 10-2021-0133837, filed on Oct. 8, 2021, and all the benefits accruing therefrom under 35 U.S.C. § 119, the content of which in its entirety is herein incorporated by reference.

### BACKGROUND

### 1. Field

Embodiments relate to a display device and a method of manufacturing the display device. More particularly, embodiments relate to a display device capable of displaying an image and a method of manufacturing the display device.

### 2. Description of the Related Art

A display device may include various electronic components, e.g., a pixel for emitting light. The pixel may be disposed on a substrate. The pixel may include driving elements and a light emitting element connected to the driving elements. The driving elements may include a transistor and a capacitor.

In such a display device, a signal is transmitted to drive the driving element. Accordingly, a driving chip or a circuit board that transmits a signal to the driving element are typically disposed on the substrate. The driving chip or circuit board may be disposed in a non-display area (e.g., a pad area, etc.) other than a display area in which pixels are disposed on the substrate.

### SUMMARY

In a display device, a pressure may be applied to place a driving chip or circuit board on a substrate. When pressure is applied to place the driving chip or circuit board on the substrate, a shape of the substrate may be deformed by the pressure. Accordingly, it is desired to prevent such deformation of the substrate by the pressure.

Embodiments may provide a display device including an electronic components.

Embodiments may provide a method of manufacturing a display device including an electronic components.

An embodiment of a display device includes a substrate including a display area and a pad area positioned at one side of the display area, a first pad electrode disposed on the pad area of the substrate, a second pad electrode disposed on the pad area of the substrate to be spaced apart from the first pad electrode, a dam structure disposed between the first pad electrode and the second pad electrode, an adhesive member disposed on the first pad electrode, the second pad electrode and the dam structure, where the adhesive member includes a first conductive ball, a second conductive ball and a resin, and an electronic component disposed on the adhesive member.

In an embodiment, the first conductive ball and the second conductive ball may be spaced apart from each other by the dam structure, the first conductive ball may be in contact with the first pad electrode, and the second conductive ball may be in contact with the second pad electrode.

In an embodiment, the dam structure may include a photo-curable polymer material.

In an embodiment, the resin may include a thermosetting polymer material.

In an embodiment, the dam structure may include a photo-curable polymer material, and the resin may include a thermosetting polymer material.

In an embodiment, the electronic component may be a driving chip or a circuit board.

In an embodiment, the electronic component may include a first connection electrode in contact with the first conductive ball, and a second connection electrode in contact with the second conductive ball.

In an embodiment, the display device may further include a plurality of driving elements disposed on the display area of the substrate and a plurality of light emitting elements disposed on the plurality of driving elements and connected to the plurality of driving elements, and the first pad electrode and the second pad electrode may be electrically connected to the plurality of driving elements and the plurality of light emitting elements.

An embodiment of a method of manufacturing a display device includes providing a first pad electrode and a second pad electrode spaced apart from the first pad electrode on a pad area of a substrate, where the substrate includes a display area and the pad area positioned at one side of the display area, forming a dam structure including a photo-curable polymer material between the first pad electrode and the second pad electrode, curing the dam structure using light, forming an adhesive member on the first pad electrode, the second pad electrode and the dam structure, where the adhesive member includes a first conductive ball, a second conductive ball, and a resin, and disposing an electronic component on the adhesive member.

In an embodiment, the forming the adhesive member may include applying the first conductive ball and the resin in a way such that the first pad electrode and the first conductive ball are in contact with each other, and applying the second conductive ball and the resin in a way such that the second pad electrode and the second conductive ball are in contact with each other.

In an embodiment, the first conductive ball and the second conductive ball may be spaced apart from each other by the dam structure.

In an embodiment, the forming the adhesive member may further include applying the resin on the first conductive ball, the second conductive ball, and the dam structure.

In an embodiment, the disposing the electronic component may include disposing a first connection electrode on a lower surface of the electronic component to overlap the first conductive ball and disposing a second connection electrode on the lower surface of the electronic component to overlap the second conductive ball.

In an embodiment, the resin may include a thermosetting polymer material.

In an embodiment, the method may further include, after the disposing the electronic component, curing the adhesive member by applying heat and pressure.

In an embodiment, the forming the dam structure may include applying the photo-curable polymer material by an inkjet process.

In an embodiment, the forming the adhesive member may include applying the first conductive ball, the second conductive ball and the resin by an inkjet process.

In an embodiment, the forming the dam structure and the curing the dam structure may be performed simultaneously with each other.

In an embodiment, the electronic component may be a driving chip or a circuit board.

In embodiments of the invention, a display device includes a substrate including a display area and a pad area positioned at one side of the display area, a first pad electrode disposed on the pad area of the substrate, a second pad electrode disposed on the pad area of the substrate to be spaced apart from the first pad electrode, a dam structure disposed between the first pad electrode and the second pad electrode, an adhesive member disposed on the first pad electrode, the second pad electrode, and the dam structure, where the adhesive member includes a first conductive ball, a second conductive ball, and a resin and an electronic component disposed on the adhesive member. In such embodiments, the dam structure may include a photo-curable polymer material and may be formed by an inkjet process. In such embodiments, the adhesive member may include a thermosetting polymer material, and may be formed by an inkjet process.

In such embodiments, the first conductive ball and the second conductive ball may be disposed to overlap only the first pad electrode and the second pad electrode, respectively, by the dam structure. Accordingly, when pressure is applied to the electronic component, pressure may be applied only to portions in which the first conductive ball and the second conductive ball are disposed, thereby effectively preventing the display device from being deformed by the pressure applied to the display device.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to an embodiment.

FIG. 2A is a cross-sectional view illustrating an embodiment taken along line I-I′ of

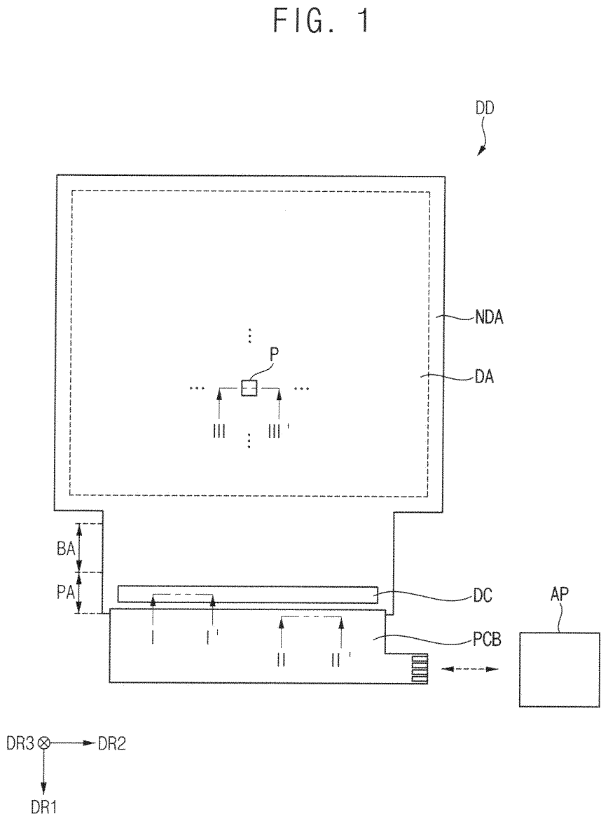

FIG. 1.

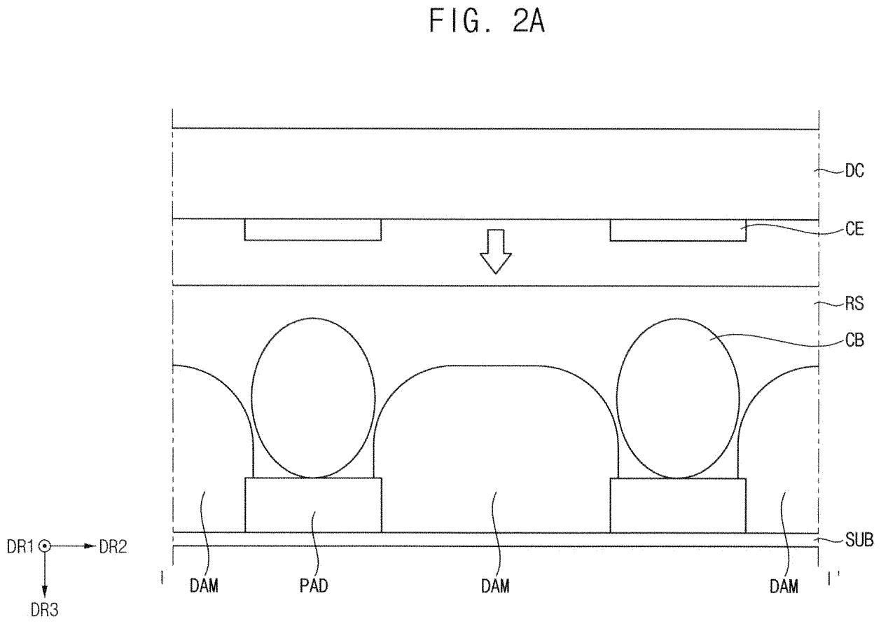

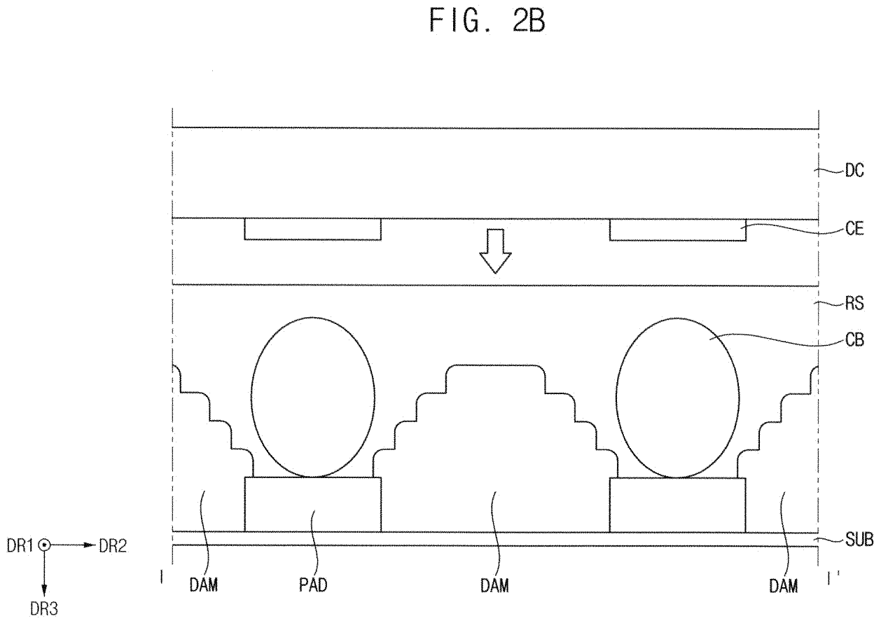

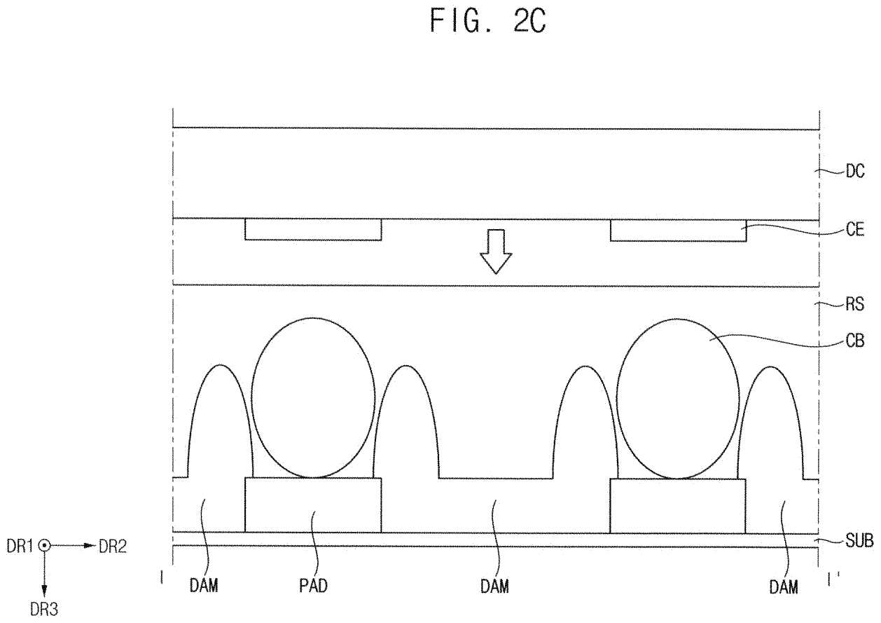

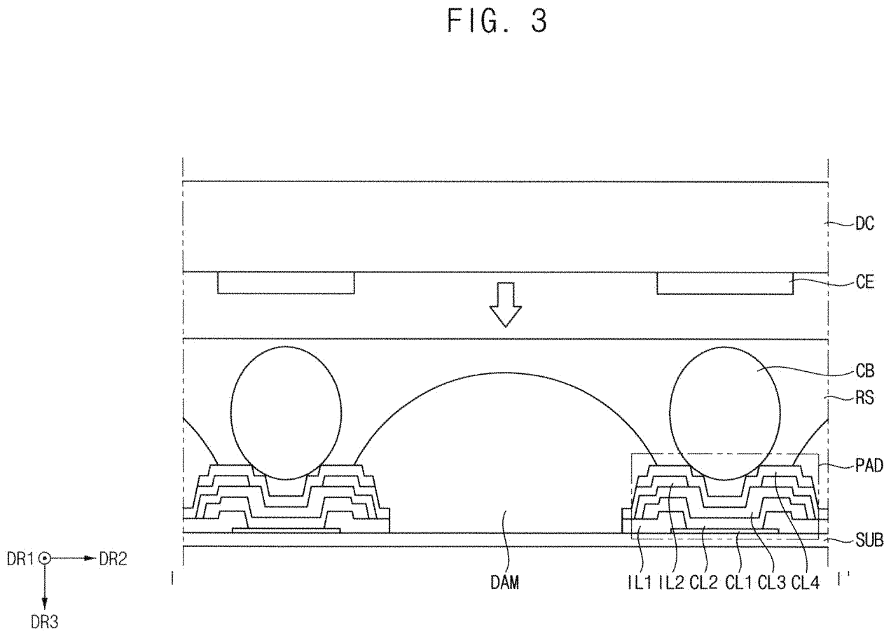

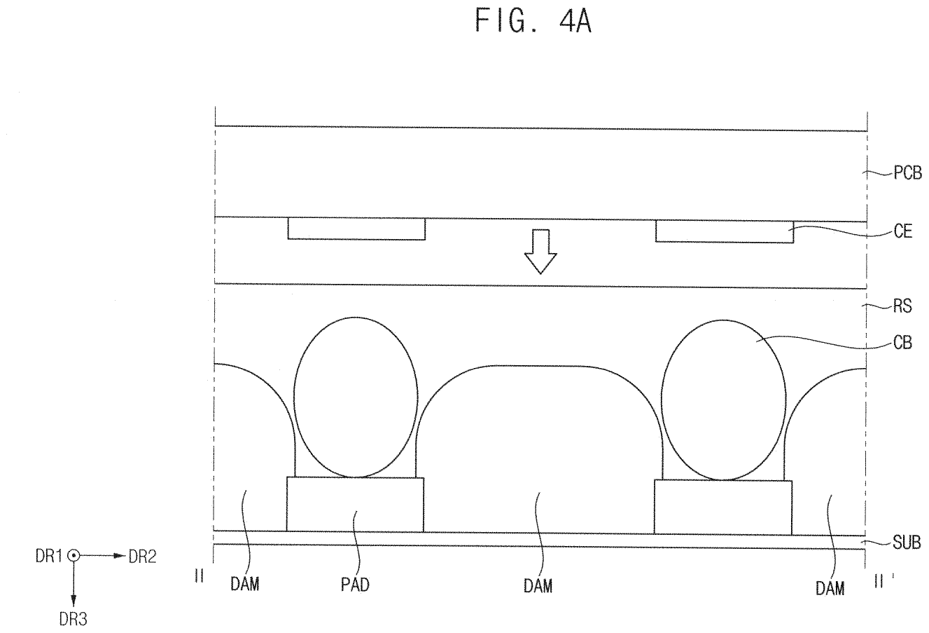

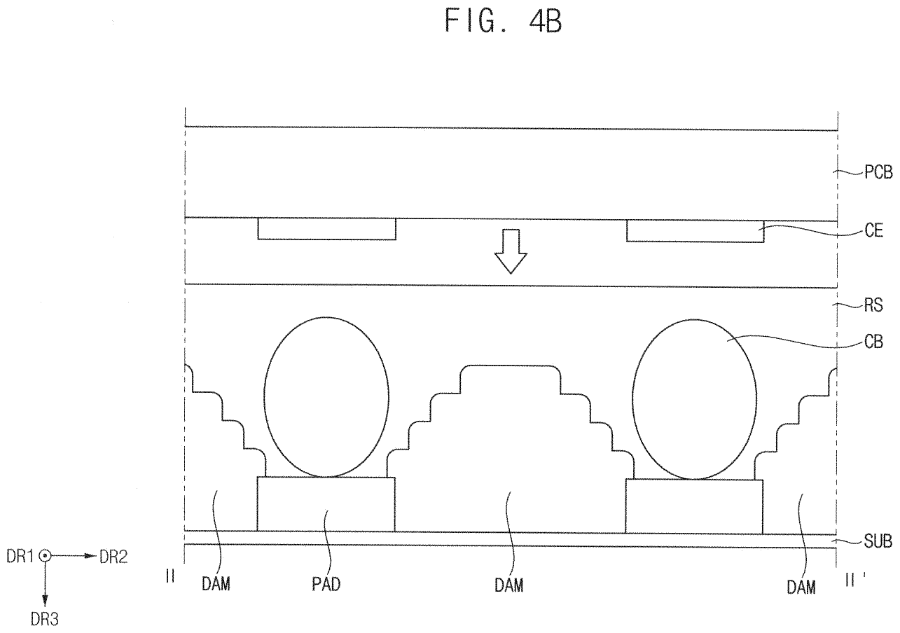

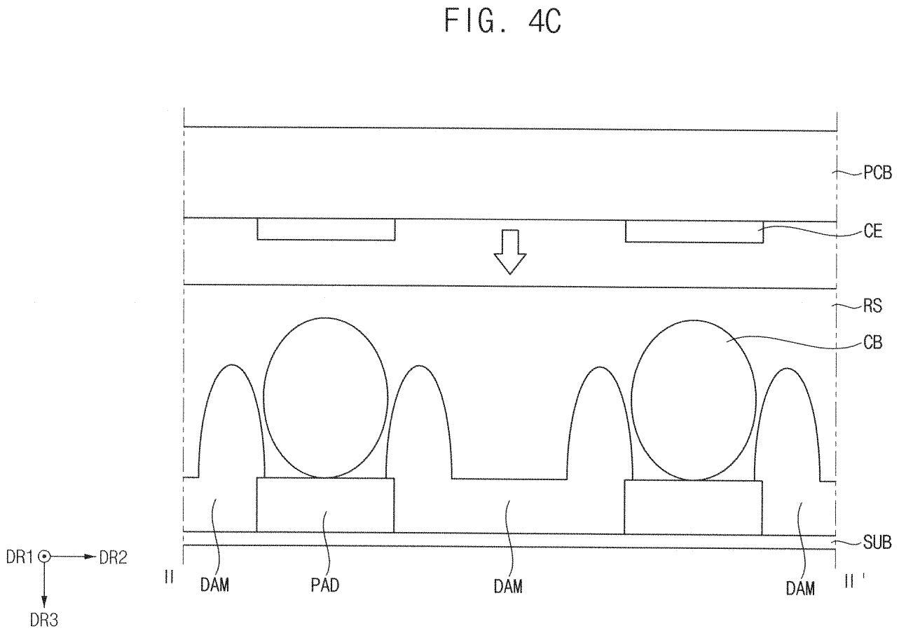

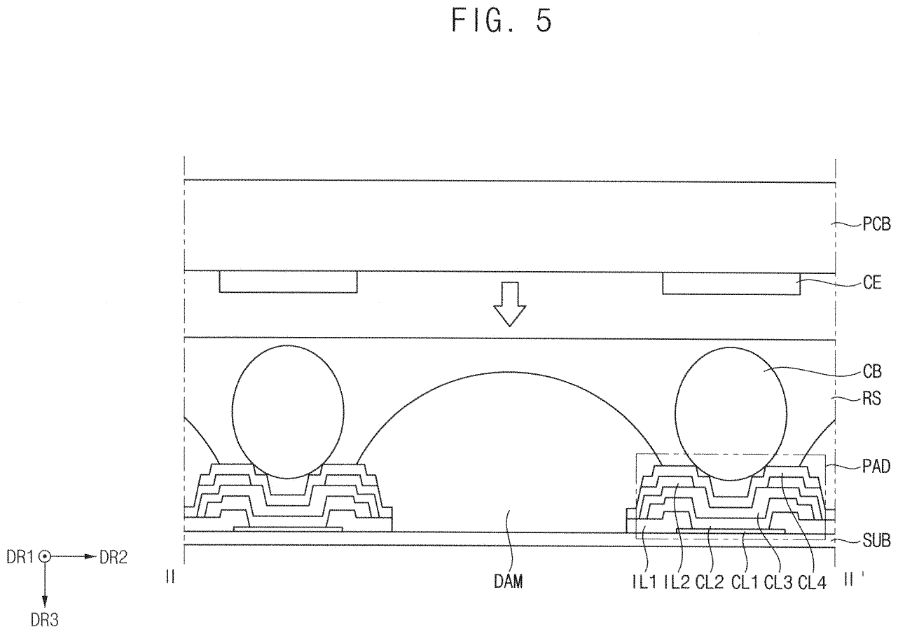

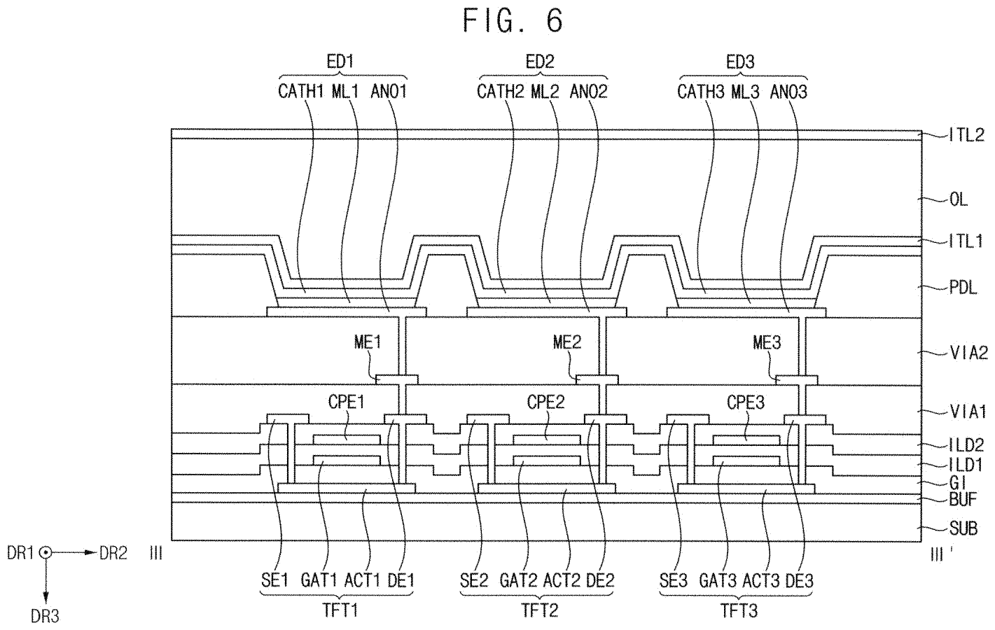

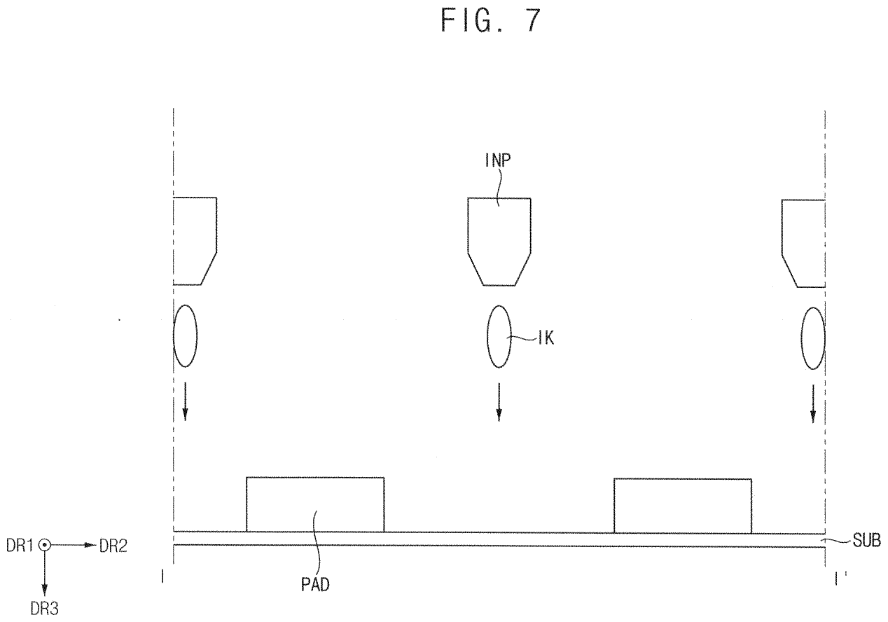

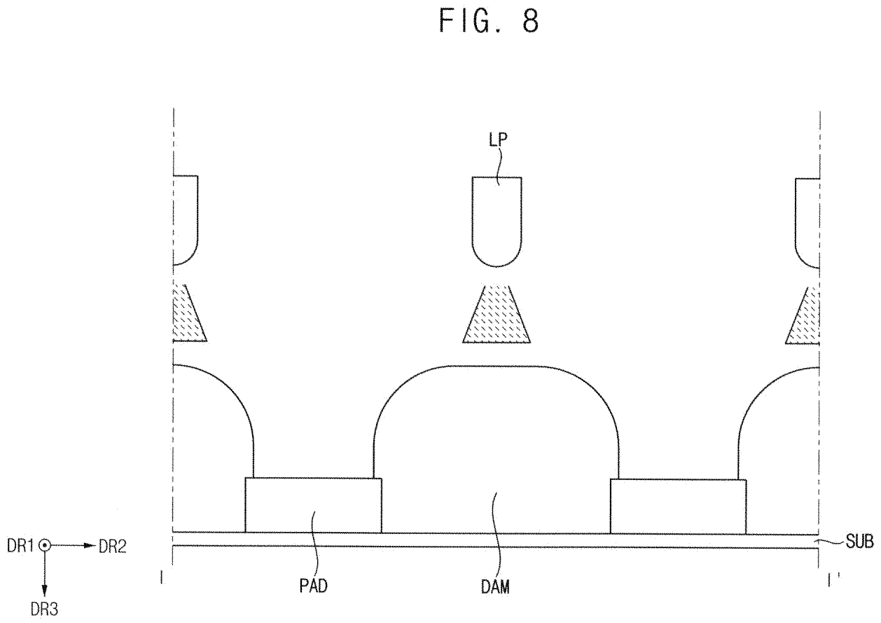

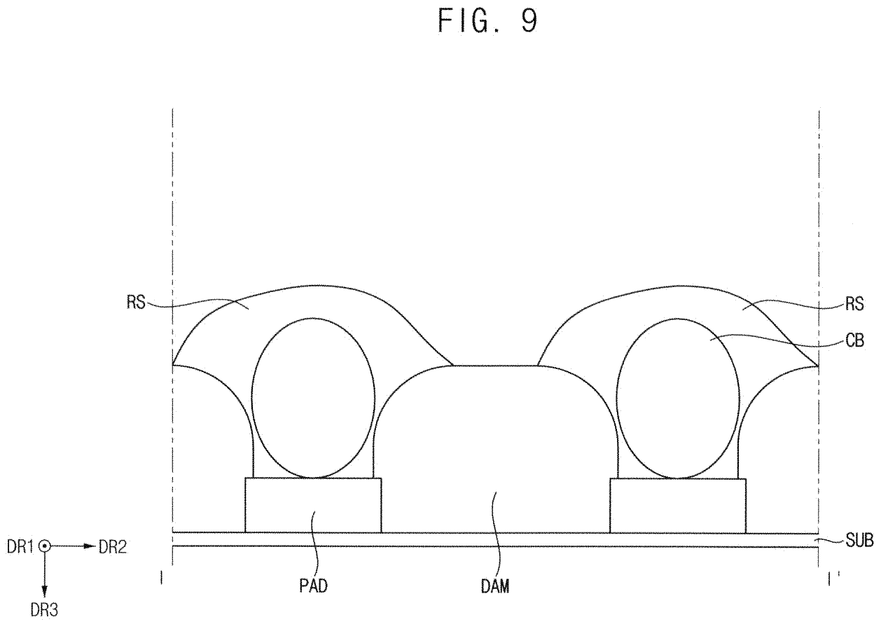

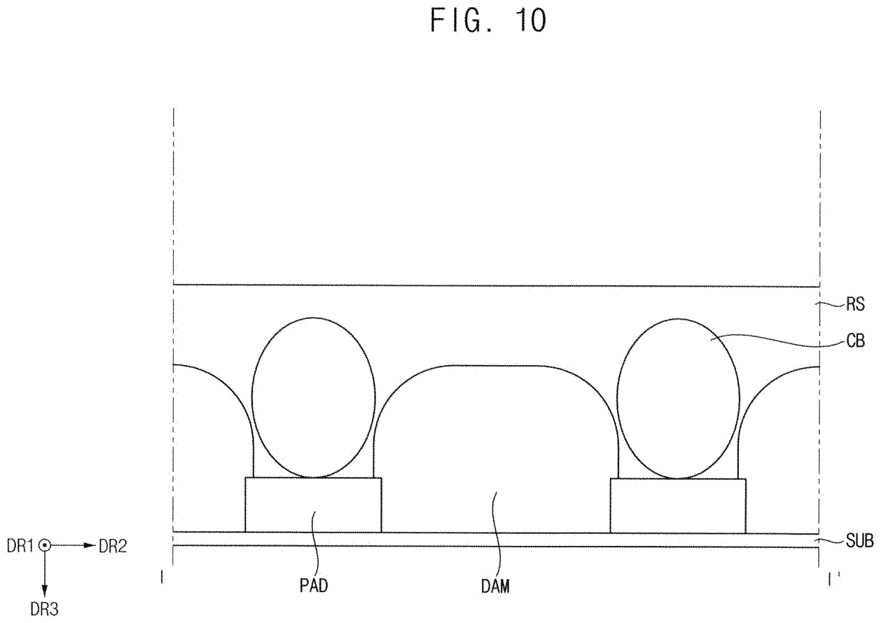

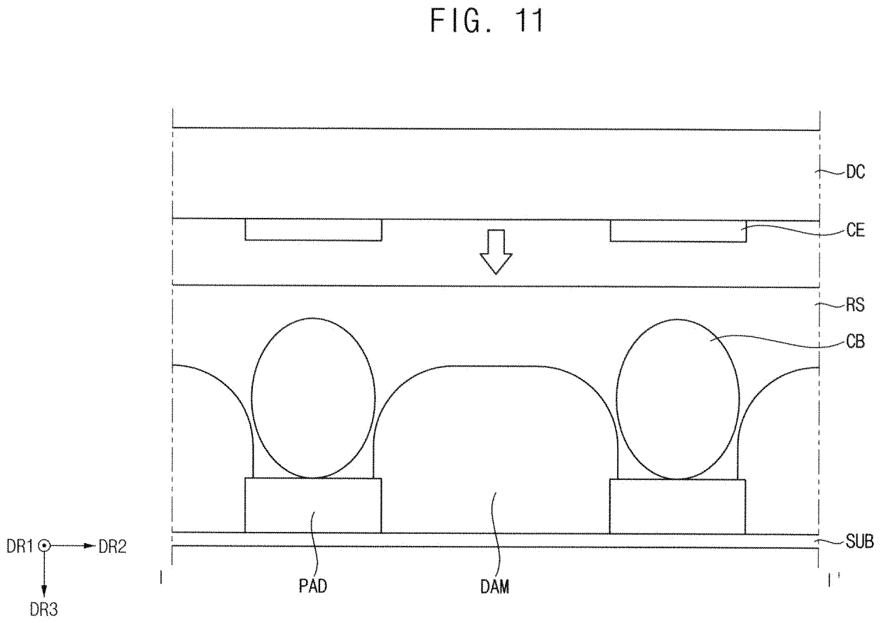

FIG. 2B is a cross-sectional view illustrating an embodiment taken along line I-I′ of FIG. 1.

FIG. 2C is a cross-sectional view illustrating an embodiment taken along line I-I′ of FIG. 1.

FIG. 3 is a cross-sectional view illustrating an embodiment taken along line I-I′ of FIG. 1.

FIG. 4A is a cross-sectional view illustrating an embodiment taken along line II-II′ of FIG. 1.

FIG. 4B is a cross-sectional view illustrating an embodiment taken along line II-II′ of FIG. 1.

FIG. 4C is a cross-sectional view illustrating an embodiment taken along line II-II′ of FIG. 1.

FIG. 5 is a cross-sectional view illustrating an embodiment taken along line II-II′ of FIG. 1.

FIG. 6 is a cross-sectional view illustrating an embodiment taken along line of FIG. 1.

FIGS. 7 to 11 are views illustrating an embodiment of a method of manufacturing the display device of FIG. 1.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

FIG. 1 is a plan view illustrating a display device according to an embodiment.

Referring to FIG. 1, an embodiment of a display device DD may include a display area DA and a non-display area NDA.

A plurality of pixels P may be disposed in the display area DA. The plurality of pixels P may be generally disposed in the display area DA. In an embodiment, for example, the plurality of pixels P may be arranged in a matrix form in the display area DA. In such an embodiment, the plurality of pixels P may be disposed along a column extending in the first direction DR1 and a row extending in the second direction DR2 in the display area DA. The first direction DR1 and the second direction DR2 may be defined as directions crossing each other. However, this is only an example, and alternatively, the plurality of pixels P may be arranged in other shapes in the display area DA.

Each of the plurality of pixels P may include driving elements and a light emitting elements. The light emitting elements may be electrically connected to the driving elements. The driving elements may include a transistor and a capacitor. The driving elements may serve to transmit an externally transmitted signal to the light emitting elements. The light emitting elements may emit light by receiving the signal. In such an embodiment, the light emitting elements may include various materials emitting light. The light emitting elements may be an organic light emitting elements or an inorganic light emitting elements.

The non-display area NDA may be positioned on at least one side of the display area DA. In an embodiment, for example, as illustrated in FIG. 1, the non-display area NDA may be positioned to surround the display area DA. Alternatively, the non-display area NDA may be positioned on only one side of the display area DA. A plurality of drivers may be disposed in the non-display area NDA. The plurality of drivers may include a gate driver, a light emitting driver, a timing controller, a gamma voltage compensator, a power voltage generator, or the like. The plurality of drivers may generate a signal for driving the plurality of pixels P and transmit the signal to the plurality of pixels P.

The non-display area NDA may include a bending area BA. The bending area BA may be positioned in the first direction DR1 of the display area DA. A length of the bending area BA in the second direction DR2 may be shorter than a length of the display area DA in the second direction DR2. The bending area BA may be bent in the third direction DR3. The third direction DR3 may be defined as a direction perpendicular to the first direction DR1 and the second direction DR2.

Also, a plurality of electronic components may be disposed in the non-display area NDA. The plurality of electronic components may be disposed on one side in the first direction DR1 of the bending area BA. The plurality of electronic components may include a driving chip DC, a circuit board PCB, or the like. The driving chip DC and the circuit board PCB may be electrically connected to the display device DD by a plurality of pad electrodes. Accordingly, the plurality of pad electrodes may be disposed in an area of the non-display area NDA positioned on one side in the first direction DR1 of the bending area BA, and the area may be defined as the pad area PA. The driving chip DC and the circuit board PCB may serve to transmit an externally transmitted signal to the plurality of pixels P. The circuit board PCB may be connected to a central processing unit AP. The central processing unit AP may generate a signal to drive the plurality of pixels P. The plurality of drivers and the driving chip DC may drive the plurality of pixels P based on a plurality of signals generated by the central processing unit AP.

FIG. 1 shows an embodiment where the display device DD has a chip on plastic (“COP”) structure, but not being limited thereto. Alternatively, the display device DD may have a chip on film (“COF”) structure. In such an embodiment, the driving chip DC may be disposed on a separate film connected to the display device DD.

FIG. 2A is a cross-sectional view illustrating an embodiment taken along line I-I′ of FIG. 1, FIG. 2B is a cross-sectional view illustrating an embodiment taken along line I-I′ of FIG. 1 and FIG. 2C is a cross-sectional view illustrating an embodiment taken along line I-I′ of FIG. 1.

Referring to FIGS. 1 and 2A, an embodiment of the display device DD may include a substrate SUB, a plurality of pad electrodes PAD, a dam structure DAM, a plurality of conductive balls CB, a resin RS, a driving chip DC, and a plurality of connection electrodes CE.

The substrate SUB may include plastic. In an embodiment, for example, the substrate SUB may include a polymer material such as polyimide, and may have flexible properties. However, this is only an example, and alternatively, the polymer material included in the substrate SUB may be selected from various materials other than polyimide.

The plurality of pad electrodes PAD may be disposed on the substrate SUB. The plurality of pad electrodes PAD may be disposed to be spaced apart from each other in the second direction DR2. The plurality of pad electrodes PAD may include a conductive material. In an embodiment, for example, the plurality of pad electrodes PAD may include a metal, an alloy, a metal oxide, a transparent conductive material, or the like. In an embodiment, the material of the plurality of pad electrodes PAD may include at least one selected from silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”) and the like. These may be used alone or in combination with each other. However, this is only an example, and alternatively, various conductive materials other than the above materials may be included the plurality of pad electrodes PAD.

The dam structure DAM may be disposed between the plurality of pad electrodes PAD. The dam structure DAM may include a photo-curable polymer material. The photo-curable polymer material may be cured by light. In an embodiment, for example, the light may be ultraviolet. The dam structure DAM may have a higher height than the plurality of pad electrodes PAD. The plurality of pad electrodes PAD may be spaced apart from each other by the dam structure DAM. Although FIG. 2A shows an embodiment where the dam structure DAM is has a semicircular shape, this is only an example, and a shape of the dam structure DAM may not be limited thereto. In an alternative embodiment, for example, the dam structure DAM may have a tapered shape. Alternatively, as illustrated in FIG. 2B, the dam structure DAM may have a step shape in which the width becomes narrow while having a step as the height increases. Alternatively, as illustrated in FIG. 2C, the dam structure DAM may have both side portions protruding and a central portion between the opposing side portions concave. However, this is only an example, and alternatively, the dam structure DAM may have various shapes determined to allow the plurality of pad electrodes PAD to be spaced apart from each other.

The plurality of conductive balls CB may be disposed on the plurality of pad electrodes PAD. The plurality of conductive balls CB may contact the plurality of pad electrodes PAD while overlapping the plurality of pad electrodes PAD. In an embodiment, the plurality of conductive balls CB may be disposed to overlap only the plurality of pad electrodes PAD by the dam structure DAM. In such an embodiment, the dam structure DAM may serve to fix the plurality of conductive balls CB to be disposed only at specific positions. The resin RS may be disposed to cover the plurality of conductive balls CB and the dam structure DAM. The resin RS may include a thermosetting polymer material. The plurality of conductive balls CB and the resin RS may be defined as an adhesive member. In an embodiment, for example, the adhesive member may be an anisotropic conductive film.

The driving chip DC may be disposed on the adhesive member. The plurality of connection electrodes CE may be disposed on a lower surface of the driving chip DC. The plurality of connection electrodes CE may overlap the plurality of pad electrodes PAD. In such an embodiment, the plurality of conductive balls CB overlap the plurality of pad electrodes PAD, such that the plurality of connection electrodes CE may also overlap the plurality of conductive balls CB.

Pressure and heat may be applied to the driving chip DC by the pressing member. As pressure is applied so that the plurality of connection electrodes CE contact the conductive balls CB, the plurality of connection electrodes CE and the plurality of conductive balls CB may contact each other. At this time, after being compressed, a portion where the conductive ball CB and the connection electrode CE come into contact may protrude upward from the dam structure DAM, or may be located at substantially the same level as an end or a top surface of the dam structure DAM. This may be equally applied to the conductive ball CB in embodiments, which will be described with reference to the drawings to be described later.

In an embodiment, the resin RS including the thermosetting polymer material may be cured by heat. Through the processes described above, the driving chip DC and the plurality of pad electrodes PAD may be electrically connected. The plurality of pad electrodes PAD may be electrically connected to the plurality of pixels P, such that the driving chip DC and the plurality of pixels P may be electrically connected.

FIG. 3 is a cross-sectional view illustrating an embodiment taken along line I-I′ of FIG. 1. FIG. 3 may correspond to a view illustrating in detail an embodiment of the structure of the plurality of pad electrodes PAD.

Referring to FIGS. 1 and 3, an embodiment of the display device DD may include a substrate SUB, a plurality of pad electrodes PAD, a dam structure DAM, a plurality of conductive balls CB, a resin RS, a driving chip DC and a plurality of connection electrodes CE.

A plurality of pad electrodes PAD may be disposed on the substrate SUB. The plurality of pad electrodes PAD may have a structure in which a plurality of conductive layers are stacked one on another. In an embodiment, for example, each of the plurality of pad electrodes PAD may have a structure in which a first conductive layer CL1, a second conductive layer CL2, a third conductive layer CL3, and a fourth conductive layer CL4 are stacked. However, this is only an example, and alternatively, each of the plurality of pad electrodes PAD may include or be formed of at least one conductive layer. In an embodiment, insulating layers IL1 and IL2 may be disposed between some of the conductive layers. Alternatively, insulating layers may not be disposed between some of the conductive layers. In an embodiment, for example, the plurality of pad electrodes PAD may constitute a first conductive layer CL1 and a second conductive layer CL2, or may constitute the first conductive layer CL1, the second conductive layer CL2, and the first insulating layer ILL In such an embodiment, the first insulating layer IL1 may be disposed to partially overlap the first conductive layer CL1 and the second conductive layer CL2. The conductive layers CL1, CL2, CL3, CL4 and the insulating layers ILL IL2 may be simultaneously formed when a conductive material and an insulating material included in a display device to be described later are formed.

FIG. 4A is a cross-sectional view illustrating an embodiment taken along line II-II′ of FIG. 1, FIG. 4B is a cross-sectional view illustrating an embodiment taken along line II-II′ of FIG. 1, and FIG. 4C is a cross-sectional view illustrating an embodiment taken along line II-II′ of FIG. 1.

Referring to FIGS. 1 and 4A, an embodiment of the display device DD may include a substrate SUB, a plurality of pad electrodes PAD, a dam structure DAM, a plurality of conductive balls CB, a resin RS, a circuit board PCB, and a plurality of connection electrodes CE.

The substrate SUB may include plastic. In an embodiment, for example, the substrate SUB may include a polymer material such as polyimide, and may have flexible properties. However, this is only an example, and alternatively, the polymer material included in the substrate SUB may be selected from various materials other than polyimide.

The plurality of pad electrodes PAD may be disposed on the substrate SUB. The plurality of pad electrodes PAD may be disposed to be spaced apart from each other in the second direction DR2. The plurality of pad electrodes PAD may include a conductive material. In an embodiment, for example, the plurality of pad electrodes PAD may include a metal, an alloy, a metal oxide, a transparent conductive material, or the like. In an embodiment, the material of the plurality of pad electrodes PAD may include at least one selected from silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), ITO, IZO and the like. These may be used alone or in combination with each other. However, this is only an example, and alternatively, various conductive materials other than the above materials may be included in the plurality of pad electrodes PAD.

The dam structure DAM may be disposed between the plurality of pad electrodes PAD. The dam structure DAM may include a photo-curable polymer material. The photo-curable polymer material may be cured by light. In an embodiment, for example, the light may be ultraviolet. The dam structure DAM may have a higher height than the plurality of pad electrodes PAD. The plurality of pad electrodes PAD may be spaced apart from each other by the dam structure DAM. Although FIG. 4A shows an embodiment where the dam structure DAM has a semicircular shape, this is only an example, and a shape of the dam structure DAM may not be limited thereto. In an alternative embodiment, for example, the dam structure DAM may have a tapered shape. Alternatively, as illustrated in FIG. 4B, the dam structure DAM may have a step shape in which the width becomes narrow while having a step as the height increases. Alternatively, as illustrated in FIG. 4C, the dam structure DAM may have both side portions protruding and a central portion between the both side portions concave. However, this is only an example, and alternatively, the dam structure DAM may have various shapes determined to allow the plurality of pad electrodes PAD to be spaced apart from each other.

The plurality of conductive balls CB may be disposed on the plurality of pad electrodes PAD. The plurality of conductive balls CB may contact the plurality of pad electrodes PAD while overlapping the plurality of pad electrodes PAD. In an embodiment, the plurality of conductive balls CB may be disposed to overlap only the plurality of pad electrodes PAD by the dam structure DAM. In such an embodiment, the dam structure DAM may serve to fix the plurality of conductive balls CB to be disposed only at specific positions. The resin RS may be disposed to cover the plurality of conductive balls CB and the dam structure DAM. The resin RS may include a thermosetting polymer material. The plurality of conductive balls CB and the resin RS may be defined as an adhesive member. In an embodiment, for example, the adhesive member may be an anisotropic conductive film.

The circuit board PCB may be disposed on the adhesive member. The plurality of connection electrodes CE may be disposed on a lower surface of the circuit board PCB. The plurality of connection electrodes CE may overlap the plurality of pad electrodes PAD. In such an embodiment, the plurality of conductive balls CB overlap the plurality of pad electrodes PAD, such that the plurality of connection electrodes CE may overlap the plurality of conductive balls CB.

Pressure and heat may be applied to the circuit board PCB by the pressing member. Through such processes, the plurality of connection electrodes CE and the plurality of conductive balls CB may contact each other. In such an embodiment, the resin RS including the thermosetting polymer material may be cured by heat, such that the circuit board PCB and the plurality of pad electrodes PAD may be electrically connected.

The plurality of pad electrodes PAD may be electrically connected to the plurality of pixels P, such that the circuit board PCB and the plurality of pixels P may also be electrically connected to each other.

FIG. 5 is a cross-sectional view illustrating an embodiment taken along line II-II′ of FIG. 1. FIG. 5 may correspond to a view illustrating in detail an embodiment of the structure of the plurality of pad electrodes PAD.

Referring to FIGS. 1 and 5, an embodiment of the display device DD may include a substrate SUB, a plurality of pad electrodes PAD, a dam structure DAM, a plurality of conductive balls CB, a resin RS, a circuit board PCB and a plurality of connection electrodes CE.

A plurality of pad electrodes PAD may be disposed on the substrate SUB. The plurality of pad electrodes PAD may have a structure in which a plurality of conductive layers are stacked one on another. In an embodiment, for example, each of the plurality of pad electrodes PAD may have a structure in which a first conductive layer CL1, a second conductive layer CL2, a third conductive layer CL3, and a fourth conductive layer CL4 are stacked. However, this is only an example, and alternatively, each of the plurality of pad electrodes PAD may include or be formed of at least one conductive layer. In an embodiment, insulating layers IL1 and IL2 may be disposed between some of the conductive layers. In an embodiment, for example, the plurality of pad electrodes PAD may constitute the first conductive layer CL1 and the third conductive layer CL3, or may constitute the first conductive layer CL1, the third conductive layer CL3, and the first insulating layer ILL In such an embodiment, the first insulating layer IL1 may be disposed to partially overlap the first conductive layer CL1 and the third conductive layer CL3. Alternatively, some insulating layers may be omitted. The conductive layers CL1, CL2, CL3, CL4 and the insulating layers ILL IL2 may be simultaneously formed when a conductive material and an insulating material included in a display device to be described later are formed.

FIG. 6 is a cross-sectional view illustrating an embodiment taken along line of FIG. 1.

Referring to FIGS. 1 and 6, an embodiment of the display device DD may include a substrate SUB, a buffer layer BUF, a gate insulating layer GI, a first transistor TFT1, a second transistor TFT2, a third transistor TFT3, a first capacitor electrode CPE1, a second capacitor electrode CPE2, a third capacitor electrode CPE3, a first interlayer insulating layer ILD1, a second interlayer insulating layer ILD2, a first via insulating layer VIA1, a second via insulating layer VIA2, a first intermediate electrode ME1, a second intermediate electrode ME2, a third intermediate electrode ME3, a first light emitting element ED1, a second light emitting element ED2, a third light emitting element ED3, a pixel defining layer PDL, a first inorganic thin film encapsulation layer ITL1, an organic thin film encapsulation layer OL, and a second inorganic thin film encapsulation layer IL2.

The first transistor TFT1 may include a first active layer ACT1, a first gate electrode GAT1, a first electrode SE1, and a second electrode DE1. The second transistor TFT2 may include a second active layer ACT2, a second gate electrode GAT2, a third electrode SE2, and a fourth electrode DE2. The third transistor TFT3 may include a third active layer ACT3, a third gate electrode GAT3, a fifth electrode SE3, and a sixth electrode DE3.

The first light emitting element ED1 may include a first anode electrode ANO1, a first intermediate layer ML1, and a first cathode electrode CATH1. The second light emitting element ED2 may include a second anode electrode ANO2, a second intermediate layer ML2, and a second cathode electrode CATH2. The third light emitting element ED3 may include a third anode electrode ANO3, a third intermediate layer ML3, and a third cathode electrode CATH3. In an embodiment, the first to third cathode electrodes CATH1, CATH2, CATH3 may be integrally formed with each other as a single unitary unit.

The substrate SUB may include plastic. The substrate SUB may include a polymer material such as polyimide, and may have flexible properties. However, this is only an example, and alternatively, the polymer material of the substrate SUB may be selected from various materials other than polyimide.

The buffer layer BUF may be disposed on the substrate SUB. The buffer layer BUF may include an inorganic insulating material. In an embodiment, for example, the material of the buffer layer BUF may include at least one selected from silicon oxide (SiOx), silicon nitride (SiNx), silicon oxynitride (SiON), and the like. These may be used alone or in combination with each other. However, this is only an example, and alternatively, other insulating materials may be included in the buffer layer BUF. The buffer layer BUF may prevent metal atoms or impurities from diffusing into the first to third active layers ACT1, ACT2, ACT3. In an embodiment, the buffer layer BUF controls the speed of heat provided to the first to third active layers ACT1, ACT2, ACT3 during the crystallization process for forming the first to third active layers ACT1, ACT2, ACT3.

The first to third active layers ACT1, ACT2, ACT3 may be disposed on the buffer layer BUF. In an embodiment, the first to third active layers ACT1, ACT2, ACT3 may include a silicon semiconductor. In an embodiment, for example, materials of the first to third active layers ACT1, ACT2, ACT3 may include at least one selected from amorphous silicon and polycrystalline silicon. Alternatively, in some embodiments, the first to third active layers ACT1, ACT2, ACT3 may include an oxide semiconductor. In an embodiment, for example, materials of the first to third active layers ACT1, ACT2, ACT3 may include at least one selected from indium-gallium-zinc oxide (“IGZO”), indium-gallium oxide (“IGO”), IZO, and the like.

However, although not illustrated, a separate electrode layer may be disposed between the buffer layer BUF and the active layers ACT1, ACT2, ACT3, or an insulating layer covering the separate electrode layer may be disposed together. The separate electrode layer may serve to protect the active layers ACT1, ACT2, ACT3 to reflect light incident from below, or to serve as a lower gate electrode.

The gate insulating layer GI may be disposed on the buffer layer BUF. The gate insulating layer GI may be disposed to cover the first to third active layers ACT1, ACT2, ACT3. The gate insulating layer GI may include an insulating material. In an embodiment, for example, the material of the gate insulating layer GI may include at least one selected from silicon oxide (SiOx), silicon nitride (SiNx), silicon oxynitride (SiON), and the like. These may be used alone or in combination with each other. However, this is only an example, and alternatively, other insulating materials may be included in the gate insulating layer GI.

The first to third gate electrodes GAT1, GAT2, GAT3 may be disposed on the gate insulating layer GI. The first to third gate electrodes GAT1, GAT2, GAT3 may partially overlap the first to third active layers ACT1, ACT2, ACT3. In response to a gate signal provided to the first to third gate electrodes GAT1, GAT2, GAT3, a signal and/or a voltage may flow through the first to third active layers ACT1, ACT2, ACT3. In an embodiment, the first to third gate electrodes GAT1, GAT2, GAT3 may include a metal, an alloy, a metal oxide, a transparent conductive material, or the like. In an embodiment, for example, materials of the first to third gate electrodes GAT1, GAT2, GAT3 may include at least one selected from silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), ITO, IZO and the like. These may be used alone or in combination with each other. However, this is only an example, and alternatively, other conductive materials may be included in the first to third gate electrodes GAT1, GAT2, GAT3.

The first interlayer insulating layer ILD1 may be disposed on the gate insulating layer GI. The first interlayer insulating layer ILD1 may be disposed to cover the first to third gate electrodes GAT1, GAT2, GAT3. In an embodiment, the first interlayer insulating layer ILD1 may include an insulating material. In an embodiment, for example, the material of the first interlayer insulating layer ILD1 may include at least one selected from silicon oxide (SiOx), silicon nitride (SiNx), silicon oxynitride (SiON), and the like. These may be used alone or in combination with each other. However, this is only an example, and alternatively, other insulating materials may be included in the first interlayer insulating layer ILD1.

The first to third capacitor electrodes CPE1, CPE2, CPE3 may be disposed on the first interlayer insulating layer ILD1. The first to third capacitor electrodes CPE1, CPE2, CPE3 may overlap the first to third gate electrodes GAT1, GAT2, GAT3. The first capacitor electrode CPE1 forms a capacitor with the first gate electrode GAT1, the second capacitor electrode CPE2 forms a capacitor with the second gate electrode GAT2, and the third capacitor electrode CPE3 forms a capacitor with the third gate electrode GAT3. The first to third capacitor electrodes CPE1, CPE2, CPE3 may include substantially a same material as the first to third gate electrodes GAT1, GAT2, GAT3.

The second interlayer insulating layer ILD2 may be disposed on the first interlayer insulating layer ILD1. The second interlayer insulating layer ILD2 may be disposed to cover the first to third capacitor electrodes CPE1, CPE2, CPE3. In an embodiment, the second interlayer insulating layer ILD2 may include an insulating material. In an embodiment, for example, the material of the second interlayer insulating layer ILD2 may include at least one selected from silicon oxide (SiOx), silicon nitride (SiNx), silicon oxynitride (SiON), and the like. These may be used alone or in combination with each other. However, this is only an example, and alternatively, other insulating materials may be included in the second interlayer insulating layer ILD2.

The first to sixth electrodes SE1, SE2, SE3, DE1, DE2, DE3 may be disposed on the second interlayer insulating layer ILD2. The first electrode SE1 and the second electrode DE1 may contact the first active layer ACT1 through a contact hole, respectively. The third electrode SE2 and the fourth electrode DE2 may contact the second active layer ACT2 through a contact hole, respectively. The fifth electrode SE3 and the sixth electrode DE3 may contact the third active layer ACT3 through a contact hole, respectively. In an embodiment, each of the first to sixth electrodes SE1, SE2, SE3, DE1, DE2, DE3 may include a metal, an alloy, a metal oxide, a transparent conductive material, or the like. In an embodiment, for example, materials of the first to sixth electrodes SE1, SE2, SE3, DE1, DE2, DE3 may include at least one selected from silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), ITO, IZO and the like. These may be used alone or in combination with each other. However, this is only an example, and alternatively, other conductive materials may be included in the first to sixth electrodes SE1, SE2, SE3, DE1, DE2, DE3.

The first via insulating layer VIA1 may be disposed on the second interlayer insulating layer ILD2. The first via insulating layer VIA1 may be disposed to cover the first to sixth electrodes SE1, SE2, SE3, DE1, DE2, DE3. The first via insulating layer VIA1 may have a substantially flat top surface. In an embodiment, the first via insulating layer VIA1 may include an organic insulating material. In an embodiment, for example, the material of the first via insulating layer VIA1 may include at least one selected from photoresist, polyacrylic resin, polyimide resin, acrylic resin, and the like. These may be used alone or in combination with each other. However, this is only an example, and alternatively, other insulating materials may be included in the first via insulating layer VIAL

The first to third intermediate electrodes ME1, ME2, ME3 may be disposed on the first via insulating layer VIAL The first intermediate electrode ME1 may contact the second electrode DE1 through the contact hole, the second intermediate electrode ME2 may contact the fourth electrode DE2 through the contact hole, and the third intermediate electrode ME3 may contact the sixth electrode DE3 through a contact hole. In an embodiment, each of the first to third intermediate electrodes ME1, ME2, and ME3 may include a metal, an alloy, a metal oxide, a transparent conductive material, or the like. In an embodiment, materials of the first to third intermediate electrodes ME1, ME2, ME3 may include at least one selected from silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), ITO, IZO and the like. These may be used alone or in combination with each other. However, this is only an example, and alternatively, other conductive materials may be included in the first to third intermediate electrodes ME1, ME2, ME3.

The second via insulating layer VIA2 may be disposed on the first via insulating layer VIAL The second via insulating layer VIA2 may be disposed to cover the first to third intermediate electrodes ME1, ME2, ME3. The second via insulating layer VIA2 may have a substantially flat top surface. In an embodiment, the second via insulating layer VIA2 may include an organic insulating material. In an embodiment, for example, the material of the second via insulating layer VIA2 include at least one selected from photoresist, polyacrylic resin, polyimide resin, acrylic resin, and the like. These may be used alone or in combination with each other. However, this is only an example, and alternatively, other insulating materials may be included in the second via insulating layer VIA2.

The first to third anode electrodes ANO1, ANO2, ANO3 may be disposed on the second via insulating layer VIA2. The first to third anode electrodes ANO1, ANO2, ANO3 may contact the first to third intermediate electrodes ME1, ME2, ME3. In an embodiment, each of the first to third anode electrodes ANO1, ANO2, ANO3 may include a metal, an alloy, a metal oxide, a transparent conductive material, or the like. In an embodiment, for example, materials of the first to third anode electrodes ANO1, ANO2, ANO3 may include at least one selected from silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), ITO, IZO and the like. These may be used alone or in combination with each other. However, this is only an example, and alternatively, other conductive materials may be included in the first to third anode electrodes ANO1, ANO2, ANO3.

The pixel defining layer PDL may be disposed on the second via insulating layer VIA2. Openings exposing the first to third anode electrodes ANO1, ANO2, ANO3 may be defined or formed in the pixel defining layer PDL. In an embodiment, the pixel defining layer PDL may include an organic material. In an embodiment, materials of the pixel defining layer PDL may include at least one selected from photoresists, polyacrylic resins, polyimide resins, and acrylic resins. However, this is only an example, and alternatively, other insulating materials may be included in the pixel defining layer PDL.

The first to third intermediate layers ML1, ML2, ML3 may be respectively disposed on the first to third anode electrodes ANO1, ANO2, ANO3. The first to third intermediate layers ML1, ML2, ML3 may include an organic material emitting light of a preset color. The first to third intermediate layers ML1, ML2, ML3 may emit light based on the potential difference between the first to third anode electrodes ANO1, ANO2, ANO3 and the first to third cathode electrodes CATH1, CATH2, CATH3. In such an embodiment, the first to third intermediate layers ML1, ML2, ML3 may include an electron injection layer, an electron transport layer, a light emitting layer, a hole transport layer, and a hole injection layer, respectively.

The first to third light emitting elements ED1, ED2, ED3 may emit light having the same color as each other. In an embodiment, for example, all of the first to third light emitting elements ED1, ED2, ED3 may emit blue light. Alternatively, the first to third light emitting elements ED1, ED2, ED3 may emit light of different colors from each other. In an embodiment, for example, the first to third light emitting elements ED1, ED2, ED3 may respectively emit red light, green light, and blue light.

The first to third cathode electrodes CATH1, CATH2, CATH3 may be disposed on the first to third intermediate layers ML1, ML2, ML3. The first to third cathode electrodes CATH1, CATH2, CATH3 may include a metal, an alloy, a metal oxide, a transparent conductive material, or the like. In an embodiment, for example, materials of the first to third cathode electrodes CATH1, CATH2, CATH3 may include at least one selected from silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), ITO, IZO and the like. These may be used alone or in combination with each other. However, this is only an example, and alternatively, other conductive materials may be included in the first to third cathode electrodes CATH1, CATH2, CATH3.

For convenience of description, the cathode electrode may be divided into the first to third cathode electrodes CATH1, CATH2, CATH3. In such an embodiment, the first to third cathode electrodes CATH1, CATH2, CATH3 may be integrally formed with each other as a single unitary unit.

A thin film encapsulation layer may be disposed on the first to third cathode electrodes CATH1, CATH2, CATH3. The thin film encapsulation layer may serve to protect the first to third light emitting elements ED1, ED2, ED3 from external moisture, heat, impact, and the like. The thin film encapsulation layer may have a structure in which a first inorganic thin film encapsulation layer ITL1, an organic thin film encapsulation layer OL, and a second inorganic thin film encapsulation layer IL2 are stacked one on another. In such an embodiment, the organic thin film encapsulation layer OL may have a relatively thicker thickness than the first and second inorganic thin film encapsulation layers ITL1, ITL2 and may have a flat top surface.

FIGS. 7 to 11 are views illustrating an embodiment of a method of manufacturing the display device of FIG. 1.

Referring to FIG. 7, a plurality of pad electrodes PAD may be disposed on the substrate SUB. The substrate SUB may include plastic. In an embodiment, for example, the substrate SUB may include a polymer material such as polyimide, and thus the substrate SUB may have flexible properties. The plurality of pad electrodes PAD may be disposed to be spaced apart from each other in the second direction DR2. Ink IK may be applied between the plurality of pad electrodes PAD. The ink IK may include photo-curable polymer materials. The ink IK may be applied by the inkjet member INP.

Referring to FIG. 8, the applied ink IK may be cured to form a dam structure DAM. The dam structure DAM may be cured using light. In an embodiment, for example, the dam structure DAM may be cured using ultraviolet light. In an embodiment, the light curing member LP may radiate light to the ink IK. The dam structure DAM may be formed between the plurality of pad electrodes PAD. Curing of the dam structure DAM may proceed simultaneously with application of the ink IK. Accordingly, the ink IK having fluidity is applied between the plurality of pad electrodes PAD and then cured immediately, thereby filling the spaces between the plurality of pad electrodes PAD.

Referring to FIG. 9, an adhesive member may be provided or disposed on the plurality of pad electrodes PAD and the dam structure DAM. The adhesive member may include a plurality of conductive balls CB and a resin RS. A mixture of the plurality of conductive balls CB and the resin RS may be applied on the plurality of pad electrodes PAD. The plurality of conductive balls CB and the resin RS may be applied by an inkjet process. The resin RS may include a thermosetting polymer material. The plurality of conductive balls CB may not be disposed in the space between the plurality of pad electrodes PAD by the dam structure DAM. Accordingly, the plurality of conductive balls CB may be disposed to overlap only the plurality of pad electrodes PAD.

Referring to FIG. 10, the resin RS may be applied to have a sufficient height by an inkjet process. The resin RS may be entirely coated on the conductive balls CB and the dam structure DAM. Through such processes described above, electronic components (e.g., the aforementioned driving chip DC, circuit board PCB, etc.) disposed on the adhesive member may be firmly coupled to the substrate SUB.

Referring to FIG. 11, the driving chip DC may be disposed over the adhesive member. The plurality of connection electrodes CE may be disposed on a lower surface of the driving chip DC. The plurality of connection electrodes CE may be disposed to overlap the plurality of pad electrodes PAD, such that the plurality of connection electrodes CE may also overlap the plurality of conductive balls CB.

The driving chip DC may receive heat and pressure by the pressing member, such that the plurality of connection electrodes CE may contact the plurality of conductive balls CB by the pressure applied by the pressing member. In addition, the resin RS including the thermosetting polymer material may be cured by heat applied by the pressing member.

When the pressure member applies pressure to the display device, the pressure may be intensively applied to portions in which the plurality of connection electrodes CE are disposed. In other words, the pressure member may apply a weak pressure or no pressure to a portion where the plurality of connection electrodes CE is not disposed. Through this, the pressing member may apply a relatively small pressure compared to the related art to bring the plurality of connection electrodes CE into contact with the plurality of conductive balls CB to be electrically connected. Accordingly, when pressure is applied to the display device by the pressing member, the substrate SUB may be effectively prevented from being deformed by other components disposed under the substrate SUB.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device, comprising:
a substrate including a display area and a pad area positioned at one side of the display area;
a first pad electrode disposed on the pad area of the substrate;
a second pad electrode disposed on the pad area of the substrate to be spaced apart from the first pad electrode;
a dam structure disposed between the first pad electrode and the second pad electrode;
an adhesive member disposed on the first pad electrode, the second pad electrode, and the dam structure, wherein the adhesive member includes a first conductive ball, a second conductive ball, and a resin; and
an electronic component disposed on the adhesive member.

2. The display device of claim 1, wherein
the first conductive ball and the second conductive ball are spaced apart from each other by the dam structure,
the first conductive ball is in contact with the first pad electrode, and
the second conductive ball is in contact with the second pad electrode.

3. The display device of claim 1,
wherein the dam structure includes a photo-curable polymer material.

4. The display device of claim 1, wherein the resin includes a thermosetting polymer material.

5. The display device of claim 1,
wherein the dam structure includes a photo-curable polymer material, and
the resin includes a thermosetting polymer material.

6. The display device of claim 1, wherein the electronic component is a driving chip or a circuit board.

7. The display device of claim 1, wherein the electronic component includes:
a first connection electrode in contact with the first conductive ball; and
a second connection electrode in contact with the second conductive ball.

8. The display device of claim 1, further comprising:
a plurality of driving elements disposed on the display area of the substrate; and
a plurality of light emitting elements disposed on the plurality of driving elements and connected to the plurality of driving elements, and
wherein the first pad electrode and the second pad electrode are electrically connected to the plurality of driving elements and the plurality of light emitting elements.

9. A method of manufacturing a display device, the method comprising:
providing a first pad electrode and a second pad electrode spaced apart from the first pad electrode on a pad area of a substrate, wherein the substrate includes a display area and the pad area positioned at one side of the display area;
forming a dam structure including a photo-curable polymer material between the first pad electrode and the second pad electrode;
curing the dam structure using light;
forming an adhesive member on the first pad electrode, the second pad electrode and the dam structure, wherein the adhesive member includes a first conductive ball, a second conductive ball, and a resin; and
disposing an electronic component on the adhesive member.

10. The method of claim 9, wherein the forming the adhesive member includes:
applying the first conductive ball and the resin in a way such that the first pad electrode and the first conductive ball are in contact with each other; and
applying the second conductive ball and the resin in a way such that the second pad electrode and the second conductive ball are in contact with each other.

11. The method of claim 10, wherein the first conductive ball and the second conductive ball are spaced apart from each other by the dam structure.

12. The method of claim 10, wherein the forming the adhesive member further includes:
applying the resin on the first conductive ball, the second conductive ball, and the dam structure.

13. The method of claim 10, wherein the disposing the electronic component includes:
disposing a first connection electrode disposed on a lower surface of the electronic component to overlap the first conductive ball and disposing a second connection electrode disposed on the lower surface of the electronic component to overlap the second conductive ball.

14. The method of claim 9, wherein the resin includes a thermosetting polymer material.

15. The method of claim 14, further comprising:
after the disposing the electronic component, curing the adhesive member by applying heat and pressure.

16. The method of claim 9, wherein the forming the dam structure includes applying the photo-curable polymer material by an inkjet process.

17. The method of claim 9, wherein the forming the adhesive member includes applying the first conductive ball, the second conductive ball and the resin by an inkjet process.

18. The method of claim 9, wherein the forming the dam structure and the curing the dam structure are performed simultaneously with each other.

19. The method of claim 9, wherein the electronic component is a driving chip or a circuit board.
